(19) United States
(12) Patent Application Publication
(10) Pub. No.: US 2023/0213627 A1
(43) Pub. Date: Jul. 6, 2023

(54) A METHOD AND ACTIVE PIXEL ARRAY FOR A TIME OF FLIGHT DETECTION

(71) Applicant: NewSight Imaging Ltd., Ness Ziona (IL)

(72) Inventors: Eyal Yatskan, Ness Ziona (IL); Uri Baror, Ness Ziona (IL)

(21) Appl. No.: 18/002,267

(22) PCT Filed: Jun. 18, 2021
(86) PCT No.: PCT/IL2021/050744

§ 371 Date: Dec. 18, 2022

Related U.S. Application Data
(60) Provisional application No. 63/040,813, filed on Jun. 18, 2020.

(51) Int. Cl. G01S 7/4863; G01S 7/4865; H01L 27/146

(52) U.S. Cl. CPC G01S 7/4863; G01S 7/4865; H01L 27/14643; G01S 17/89

(57) ABSTRACT

An array of photodiodes is provided, the array including a plurality of photodiodes arranged in groups, each group including at least a first photodiode, a second photodiode and a third photodiode; and a shutter for controlling integration time of each of the first, second and third photodiodes in the groups, facilitating detection of light by the first photodiode during a first timeslot, detection of light by the second photodiode during a second timeslot, and detection of light by the third photodiode during a third timeslot. The first, second and third timeslots are independently controlled allowing thereby detecting various portions of light radiation.

### FIELD OF INVENTION

The presently disclosed subject matter relates to a photodiode array in general, and in particular to an photodiode array for a time of flight detector.

### BACKGROUND

Light Detection and Ranging systems (LiDAR) are one of the technologies which are used for assessing distances. In the LiDAR systems a target is illuminated with a pulsed laser light, and the reflected pulse is measured.

As shown in the time graph of FIG. 1, the LiDAR system is configured to send out light pulses 10, such as a 50 ns pulses, which are reflected by objects in front of the system and are subsequently detected by the detector of the LiDAR system as reflected pulses 12. Due to the effect of time of flight, the reflected pulse 12 arrives back at the detector of the LiDAR system at a time delay 14, which is proportional to the distance between the LiDAR system and the detected object. The first readout of the detector is carried out at the end of each of the emitted pulses 10, e.g. at the end of the 50 ns time slot 16. Due to the delay of the reflected pulse 12, only a front section 20a of the reflected pulse 12, reaches the detector before the readout occurs. Accordingly, within the timeslot of the 50 ns pulse the detector reads only a portion 20a of the reflected pulse 12.

The remaining portion 20b of the reflected pulse 12, i.e. the portion of the reflected pulse 12 which reaches the detector after the end of the emitted pulses 10, e.g. at the end of the 50 ns time slot 16. Thus, the readout of the remaining portion 20b can be carried out at the beginning of a successive pulse 18. This way the LiDAR system obtains the portions 20a of the reflected pulse 12 which is received within the time of the emitted pulse 10, and the remaining portion 20a is received after the end of the emitted pulse 10.

The distance can be calculated using the equation,

$$D = \frac{1}{2} {ct}_{0} \frac{{s}_{2}}{{s}_{1} + {s}_{2}}$$

for an ideal detector. Where c is the speed of light; t₀ is the time it takes the pulse to travel to the target and back; S₁ is the amount of the light which is received by the detector at the timeslot of the emitted pulse 10, here designated as 20a; and S₂ is the amount of the light pulse which is detected after the end of the emitted pulse 10, here designated as 20a.

This way, the two readouts provide both components of the reflected pulse 12 S₁ and S₂, and the distance of the object can be calculated with the above equation.

### SUMMARY OF INVENTION

There is provided in accordance with an aspect of the presently disclosed subject matter an array of photodiodes including a plurality of photodiodes arranged in groups, each group including at least a first photodiode, a second photodiode and a third photodiode; a shutter for controlling integration time of each of the first, second and third photodiodes in the groups, facilitating detection of light by the first photodiode during a first timeslot, detection of light by the second photodiode during a second timeslot, and detection of light by the third photodiode during a third timeslot. The first, second and third timeslots are independently controlled allowing thereby detecting various portions of light radiation.

Each of the groups can further include a fourth photodiode and wherein the shutter is further configured to facilitate detection of light by the fourth photodiode during a fourth timeslot.

The second timeslot can occur after the first timeslot and the third timeslot starts at the end of the second timeslot.

The second timeslot can occur after the first timeslot and the third timeslot starts at the end of the second timeslot and wherein the fourth timeslot overlaps with a portion of the second timeslot and a portion of the third timeslot.

The array can further include a controller configured for receiving data related to amount of light detected by each one of the first, second and third photodiodes. The controller can be configured for determining length and timing of each of the first, second and third timeslots in accordance with the data.

There is provided in accordance with another aspect of the presently disclosed subject matter a time-of-flight detector including: a light source for emitting light pulses towards an object, such that the pulses are reflected back towards the detector; an array of photodiodes arranged in groups, each group including at least a first photodiode, a second photodiode and a third photodiode; a shutter for controlling integration time of each of the first, second and third photodiodes in the groups, facilitating detection of light by the first photodiode during a first timeslot, detection of light by the second photodiode during a second timeslot, and detection of light by the third photodiode during a third timeslot. The first, second and third timeslots are independently controlled allowing thereby detecting various portions the reflected pulses.

Each of the groups further can include a fourth photodiode and wherein the shutter is further configured to facilitate detection of light by the fourth photodiode during a fourth timeslot.

The time-of-flight detector can further include a controller configured for controlling operation of the light source and the shutter, and for controlling timing of the light pulses and timing of the each of the first, second and third timeslots.

The controller can be configured to end the first timeslot before the reflected pulse is expected to reach back the detector, such that light detected during the first timeslot is ambient light, the controller is further configured to start the second timeslot after the pulse of light is emitted such that light detected during the second timeslot is a first portion of the reflected pulse, and the controller is further configured to start the third timeslot at the end of the second timeslot such that light detected during the third timeslot is a second portion of the reflected pulse.

The controller can be further configured to determine the timing of the fourth time slot such that the fourth timeslot overlaps with a portion of the second timeslot and a portion of the third timeslot.

The controller can be configured for receiving data related to amount of light detected by each one of the first, second, third and fourth photodiodes, the controller is further configured for determining length and timing of each of the light pulses and the first, second, third and fourth timeslots in accordance with the data.

There is provided in accordance with yet another aspect of the presently disclosed subject matter a method for time-of-flight detection by a detector having a plurality of photodiodes, the method includes: sending light pulses towards an object, such that the pulses are reflected back towards the detector; arranging the photodiodes in groups, each group including at least a first photodiode, a second photodiode and a third photodiode; detecting light by the first photodiode during a first timeslot, detecting light by the second photodiode during a second timeslot, and detecting light by the third photodiode during a third timeslot; and controlling the timing of each of the first, second and third timeslots independently allowing thereby detecting various portions the reflected pulses.

Each of the groups further includes a fourth photodiode and wherein the step of detecting light further includes detecting light by the fourth photodiode during a fourth timeslot.

The method can further include controlling the timing of the light pulses and timing of the each of the first, second and third timeslots.

The step of controlling can include ending the first timeslot before the reflected pulse is expected to reach back the detector, such that light detected during the first timeslot is ambient light, the step of controlling further includes starting the second timeslot after the pulse of light is emitted such that light detected during the second timeslot is a first portion of the reflected pulse, and the step of controlling further includes starting the third timeslot at the end of the second timeslot such that light detected during the third timeslot is a second portion of the reflected pulse.

The step of controlling can further include determining the timing of the fourth time slot such that the fourth timeslot overlaps with a portion of the second timeslot and a portion of the third timeslot.

The method can further include receiving data related to amount of light detected by each one of the first, second, third and fourth photodiodes, and determining length and timing of each of the light pulses and the first, second, third and fourth timeslots in accordance with the data.

### BRIEF DESCRIPTION OF THE DRAWINGS

In order to understand the disclosure and to see how it may be carried out in practice, embodiments will now be described, by way of non-limiting examples only, with reference to the accompanying drawings, in which:

FIG. 1 is a graph illustration of the prior art light pulse detection;

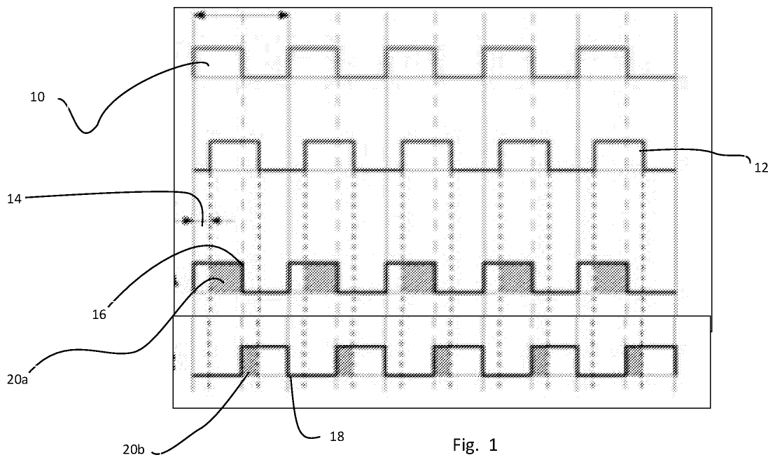

FIG. 2 is a schematic illustration of an arrangement of a photodiode array in accordance with an example of the presently disclosed subject matter;

FIG. 3 is a graph illustration of light pulse detection in accordance with an example of the presently disclosed subject matter;

FIG. 4A is a schematic illustration of a photodiode array in accordance with another arrangement of the presently disclosed subject matter; and

FIG. 4B is a schematic illustration of a photodiode array in accordance with yet another arrangement of the presently disclosed subject matter.

### DETAILED DESCRIPTION OF EMBODIMENTS

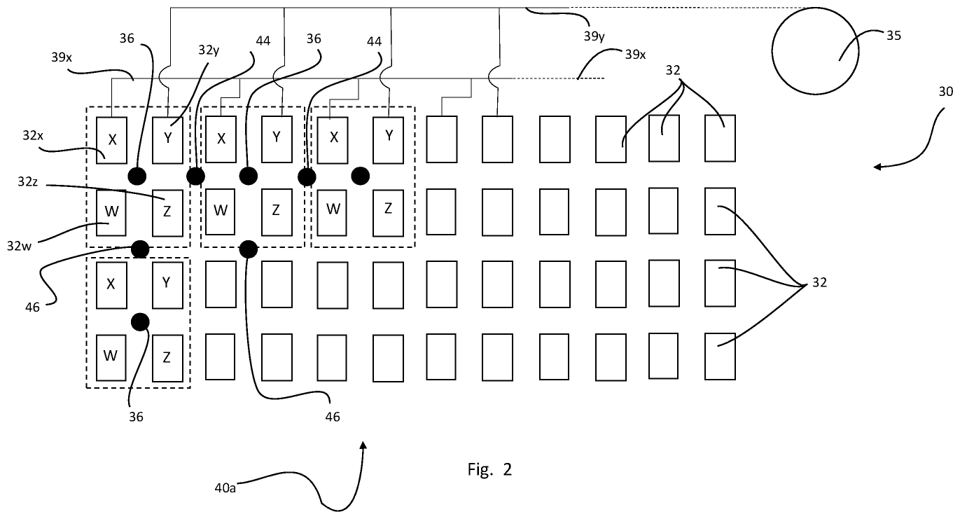

FIG. 2 shows a photodiode array 30 having a plurality of photodiodes 32 arranged in a two-dimensional array. The photodiodes 32 are configured for detecting light radiation and for allowing a detection of the light radiation by each of the photodiode at a predetermined time, such that each of the photodiodes 32 is configured to detect light at a predetermined timeslot. The photodiodes 32 can include an electronic shutter for controlling integration time of each of the photodiodes 32 such that the exposure time of each of the photodiodes 32 can be independently controlled for the predetermined timeslots. The array can further include a controller 35 for controlling and determining the timeslots of each of the photodiodes 32, and can be configured for dynamically changing the timeslots of each individual photodiode 32.

The photodiodes 32 in the array can be arranged into groups in various arrangements. In the present example the arrangement, which is generally designated 40a, includes a plurality of groups 36 in the array 30. In other words, when the photodiode array 30 is utilized to obtain a depth image, such as in time of flight (TOF) camera, each group of photodiodes 32 provides information regarding one depth pixel in the obtained image. For example, group 36 includes four photodiodes 32, designated as X, Y, W and Z, each of which being controlled independently of the others. I.e., all of the X photodiodes in the array are coupled to a single control line 39x, such that the integration time, and hence light detection, of all the X photodiodes is carried out at the same time. Similarly, all of the Y photodiodes in the array are coupled to a single control line 39y, such that light detection by all the Y photodiodes is carried out together. Although not illustrated, the same is true with regards to the Z and W photodiodes.

The photodiode array 30 can be configured such that all the photodiodes of the same designation, e.g., all the X photodiodes of all the groups 36 are controlled together, all the Y photodiodes of all the groups 36 are controlled together, etc.

According to an example the photodiode array 30 can be configured such that the exposure time of each of the photodiodes 32 within the group 36 is carried out at a predetermined time, thereby providing an exposure timeslot for each photodiode, i.e., timeslot in which the photodiode detects light. In other words, each exposure timeslot is determined as the time period during the shutter makes the photodiode available to detect light. While this duration can be a fixed duration, the timestamp of each readout can be different. For the sake of the below description, it is assumed that each timeslot has a unique timestamp.

Thus, while the X photodiodes (hereinafter first photodiodes 32x) can be configured to detect light at a first timeslot, the Y photodiodes (hereinafter second photodiodes 32y) can be configured to detect light at a second timeslot, the W photodiodes (hereinafter third photodiodes 32w) can be configured to detect light at a third timeslot, and the Z photodiodes (hereinafter fourth photodiodes 32z) can be configured to detect light at a fourth timeslot. As explained above the length of the first, second, third and fourth timeslots can be the same, however the timestamp in which each timeslot begins, and ends is unique for each of the timeslots. Thus, the timing of the exposure of each group of X, Y and Z photodiodes can be controlled.

Accordingly, the photodiode array 30 provides an image wherein each group 36 includes data obtained by four photodiodes 32x, 32y, 32w and 32z during four different timeslots.

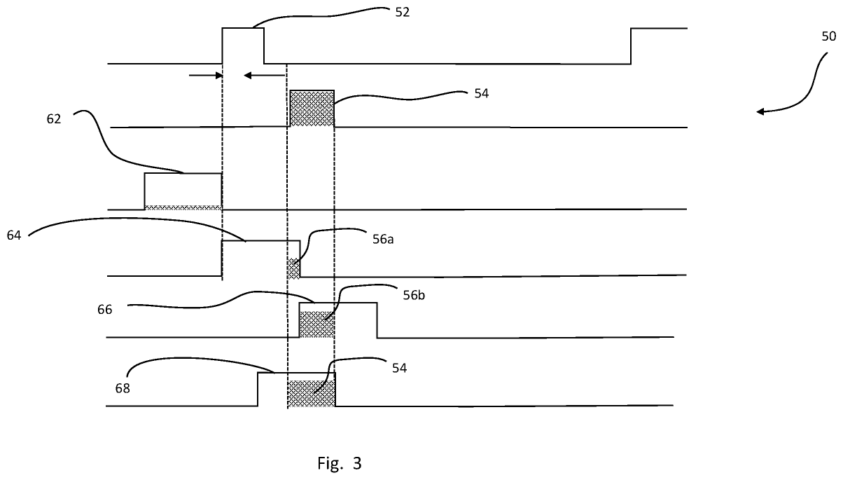

According to an example, the photodiode array 30 can be used for detecting time of flight of a pulse sent by a light source and begin being reflected from a distance object. According to this example, the photodiode array can be integrated in a time-of-flight camera having a light source configured for emitting light pulses towards an object. Reference is now made to FIG. 3, a time graph 50 showing a light pulse 52 having a predetermined width, representing a pulse of a certain duration which is sent from the time-of-flight camera towards an object (not shown). The pulse is reflected by the object, and is shown here as a reflected pulse 54, which arrives back at the time-of-flight camera with a delay directly related to the distance between the time-of-flight camera and the object.

The photodiode array 30 is configured such that photodiode 32x of each of the groups 36 has an exposure time (i.e., integration time controlled by the electronic shutter) at a first timeslot 62, i.e., all the first photodiodes 32x are exposed and available to detect light during this first timeslot 62. Similarly, photodiode 32y of each of the groups 36 has a exposure time at a second timeslot 64, i.e., all the photodiodes 32y are exposed and available to detect light during this second timeslot 64. Photodiode 32w of each of the groups 36 has a exposure time at a third timeslot 66, and photodiode 32z of each of the groups 36 has a readout at a fourth timeslot 68.

As can be clearly seen in the time graph 50, first photodiodes 32x are configured such the first timeslot 62 ends before the pulse 52 is sent and when no reflecting pulse 54 is expected. Thus, photodiodes 32x only detect ambient light 55, and do not provide any information regarding the pulse 52 reflected by the object.

Further, photodiodes 32y and 32w are configured such the second and third timeslots 64 and 66 occur after the pulse 52 is sent, such during the second and third timeslots 64 and 66 at least some of the light of the reflected pulse 54 is detected by each of the photodiodes 32y and 32w. As shown, exposure of the third photodiodes 32w is configured such that the third timeslot 66 starts at the end of the second timeslot 64 of the second photodiodes 32y. I.e., the second and third timeslots 64 and 66 do not overlap with one another, and while a first portion 56a of the reflected pulse 54 is detected by the second photodiodes 32y, a second portion 56b of the reflected pulse 54 is detected by the third photodiodes 32w.

Finally, the exposure time of the fourth photodiodes 32z is configured with a fourth timeslot 68 which occurs after the pulse 52 is sent, however in such a way that this fourth timeslot overlaps with a portion of the second timeslot 64 and a portion of the third timeslot 66. As a result, the fourth photodiodes 32z are configured to detect the entire reflected pulse 54, which is equals to the sum of the first and second portions 56a and 56b detected by the second and third photodiodes 32y and 32w.

Consequently, each group 36 in the array, provides information regarding the ambient light detected during the first timeslot 62, and allows comparison between the amount of light detected in each of the second, third and fourth timeslots 64, 66 and 68.

According to an example, the information obtained by the four photodiodes 32x, 32y, 32w and 32z of the group 36 allows time of flight calculation and determining the distance of the object, as follows:

$$D = c \frac{T O F}{2}$$

Where: D is the distance between the object and the camera, c is the speed of light, and TOF (Time of Flight) is calculated as follows:

$$T O F = {t}_{0} + Δ t \cdot \frac{{S}_{y} - {S}_{x}}{{S}_{z} - {S}_{x}}$$

Where:

t₀ is the time stamp the pulse 52 is sent, Δt is the duration of the light pulse 52.

Sₓ, S_{y} and S_{z} are the charges accumulated during the first, second, and fourth timeslots 62, 64 and 68.

It noted that the Sₓ reflects the charges accumulated due the ambient light, which is subtracted from the light S_{y} detected during the second timeslot 64 by the photodiodes 32y and is also subtracted from the light S_{z} detected during the fourth timeslot 68 by the photodiodes 32z.

In case the second photodiode 32y of one of the groups 36 does not yield enough information, i.e., the portion of the reflected pulse 54 detected at the second timeslot 64 is too little, the TOF can be calculated by using the information obtained by the third photodiode 32w, i.e., during the third timeslot 66. The latter case can occur for example when the object is at a distance and the time of flight is longer such that by the time the second timeslot 64 had ended only a small portion of the reflected pulse reached the second photodiode 32y. In this case, the reflected pulse 54 will be detected during the third timeslot 66 by the third photodiode 32w. In this case the TOF is calculated as follows:

$$T O F = {t}_{0} + Δ t \cdot \frac{{S}_{w} - {S}_{x}}{{S}_{z} - {S}_{x}}$$

Where:

t₀ is the time stamp the pulse 52 is sent, Δt is the duration of the light pulse 52.

S_{w} is the charges accumulated during the third timeslots 66 and replaces S_{y} the previous equation.

This way, each group 36 in the photodiode array 30 acquires enough information to accurately determine the time of flight under various conditions. I.e., the photodiode array 30 can determine the time of flight of an object without the effect of the ambient light. In addition, each group 36 in the photodiode array 30 acquires enough information to accurately determine the time of flight of any range, i.e., for objects located at either short or long distances. Thus, the photodiode array 30 can provide a depth image of an object wherein each depth pixel in the image is determined by the information obtained by one of the groups 36.

Moreover, the photodiode array 30 can be used to provide other ways to calculate the above TOF. For example, instead of making use of the light S_{z} detected during the fourth time slot 68 by the photodiodes 32z, the TOF can be calculated by combining the light S_{y} detected during the second time slot 64 by the photodiodes 32y, and the light S_{w} detected during the third timeslots 66. Obviously, in this case the ambient light is subtracted twice, since both photodiodes 32y and 32w are exposed to the ambient light. I.e., as follows:

$$T O F = {t}_{0} + Δ t \cdot \frac{{S}_{w} - {S}_{x}}{{S}_{y} + {S}_{w} - 2 {S}_{x}}$$

$$Or :$$

$$T O F = {t}_{0} + Δ t \cdot \frac{{S}_{y} - {S}_{x}}{{S}_{y} + {S}_{w} - 2 {S}_{x}}$$

It is noted that since each photodiode in the array is physically disposed in a certain distance from one another, when combining in one equation the lights S_{y}, S_{z}, S_{w}, Sₓ detected by the photodiodes 32y, 32z, 32w, 32x, respectively, inevitably, the physical location of each photodiode must be taken into consideration. For that, the various calculations can be carried out together and the final TOF of each group can be carried out as an average of the various calculations.

Moreover, when calculating the TOF of a certain depth pixel of the depth imaging, lights S_{y}, S_{z}, S_{w}, Sₓ can be obtain from more than one group 36. For example, when calculating the distance detected by group 36 the ambient light Sₓ can be used from the information gathered by photodiode 32x, or by the photodiode 32x of an adjacent group, or by an average of the photodiodes 32x of adjacent groups. This way, the most accurate information regarding the ambient light can be obtained.

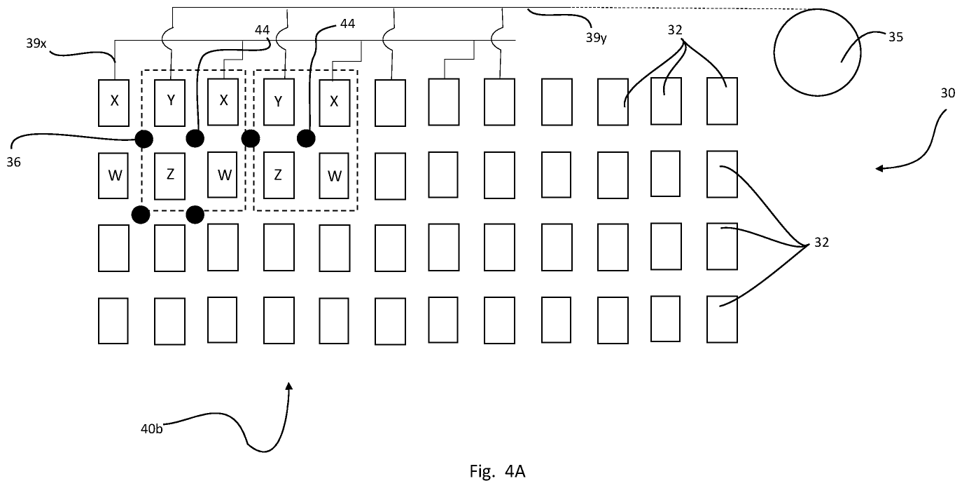

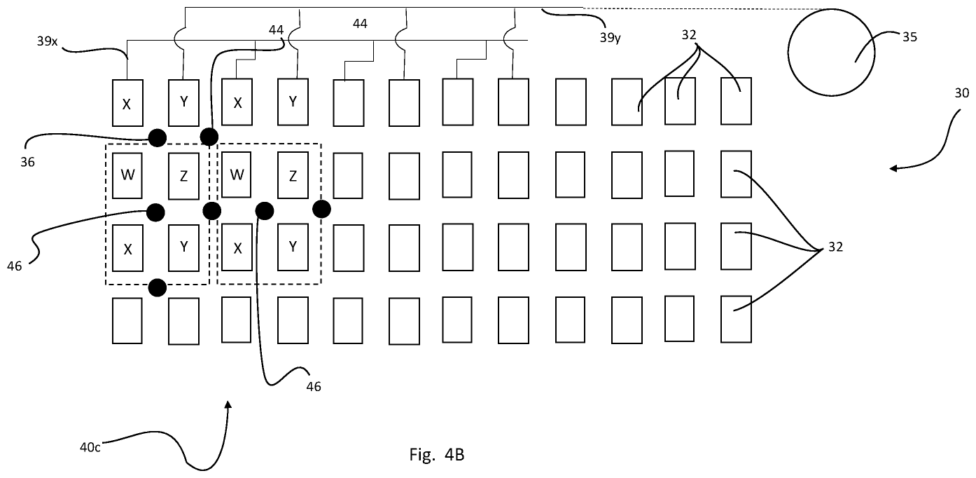

With reference to FIGS. 4A and 4B, the photodiode array 30 can be configured to dynamically allow various configurations of the groups in other arrangements. That is to say, the photodiodes 32 are arranged in the array having lines and columns, and the groups of photodiodes 32 can be dynamically arranged to form groups including various lines and columns. For example, in FIG. 2, the photodiodes 32 are arranged into groups forming a group 36, in a first arrangement 40a, in FIG. 4A, on the other hand, the same photodiodes 32 can be arranged in a second arrangement 40b, such that each group is shifted one column and each group represents group 44. I.e., the photodiodes 32 in the group provide the information in accordance with the predetermined timeslot, however the groups 44 are arranged differently, and the calculation of each group 44 is now carried out with two photodiodes of one group 36 of the first arrangement 40a of FIG. 2, and two photodiodes of a second adjacent group 36.

It is appreciated that while the location of each of the photodiodes 32x, 32y, 32w and 32z in the array 30 is fixed, the grouping of the photodiodes can be dynamic so as to compensate for the differences in the physical locations of each photodiode in the group. This way, while in the first arrangement 40a provides information obtained in four timeslots 62, 64, 66 and 68, with regards to groups 36, the second arrangement 40b provides information obtained in four timeslots 62, 64, 66 and 68, with regards to groups 44 which are shifted one column with respect to the groups 36.

Similarly, as shown in FIG. 4B, the same photodiodes 32 can be arranged in a third arrangement 40c, such that each group is shifted one line and each group represents group 46. This way, while in the first arrangement 40a provides information obtained in four timeslots 62, 64, 66 and 68, with regards to groups 36, the third arrangement 40c provides information obtained in four timeslots 62, 64, 66 and 68, with regards to groups 46 which are shifted one line with respect to the groups 36.

The various arrangements allow obtaining information of groups disposed on different locations on the photodiode array 30, such that the detector can be configured to obtain information in more than one arrangement. This way, although each group includes more than one photodiode, the resolution of the sensor is not compromised since the detector can provide information with groups disposed at various locations with respect to the photodiode array.

Moreover, the controller 35 can be configured to determine the timing of the timeslots and the pulses. For example, the controller can be configured for receiving data from the photodiodes and for determining length and timing of light pulses and the timeslots in accordance with the obtained data. This way, the time-of-flight camera can be configured to send pulses of various lengths for detecting objects of various distances. Since, the second and third timeslots are configured to detect portions of the reflected pulses, the timing of these timeslots is determined such that the pulse has enough time to reach the object and be reflected back. Consequently, the timing of the fourth timeslot is also adapted to overlap with the second and third timeslots. In addition, the first timeslot can also be adapted to end as close as possible to the start of the second timeslot, facilitating thereby accurate detection of the expected ambient light during the second and third timeslot.

According to an example, the controller can be configured to send multiple pulses for each set of timeslots, such that more light can be detected during each set of timeslots. Furthermore, the controller can adapt various arrangements, as explained hereinabove with respect to FIGS. 4A and 4B, to obtain a set of data for each depth pixel in the depth image.

Those skilled in the art to which the presently disclosed subject matter pertains will readily appreciate that numerous changes, variations, and modifications can be made without departing from the scope of the invention, mutatis mutandis.

1. An array of photodiodes comprising:
a plurality of photodiodes arranged in groups, each group including at least a first photodiode, a second photodiode and a third photodiode; and
a shutter for controlling integration time of each of the first, second and third photodiodes in said groups, facilitating detection of light by said first photodiode during a first timeslot, detection of light by said second photodiode during a second timeslot, and detection of light by said third photodiode during a third timeslot;
wherein said first, second and third timeslots are independently controlled allowing thereby detecting various portions of light radiation.

2. The array of claim 1 wherein each of said groups further includes a fourth photodiode and wherein said shutter is further configured to facilitate detection of light by said fourth photodiode during a fourth timeslot.

3. The array of claim 1 wherein said second timeslot occurs after said first timeslot and said third timeslot starts at the end of said second timeslot.

4. The array of claim 2 wherein said second timeslot occurs after said first timeslot and said third timeslot starts at the end of said second timeslot and wherein said fourth timeslot overlaps with a portion of said second timeslot and a portion of said third timeslot.

5. The array of claim 1 further comprising a controller configured for receiving data related to amount of light detected by each one of said first, second and third photodiodes.

6. The array of claim 1 wherein said controller is further configured for determining length and timing of each of the first, second and third timeslots in accordance with said data.

7. A time-of-flight detector comprising:
a light source for emitting light pulses towards an object, such that said pulses are reflected back towards the detector;
an array of photodiodes arranged in groups, each group including at least a first photodiode, a second photodiode and a third photodiode; and
a shutter for controlling integration time of each of the first, second and third photodiodes in said groups, facilitating detection of light by said first photodiode during a first timeslot, detection of light by said second photodiode during a second timeslot, and detection of light by said third photodiode during a third timeslot;
wherein said first, second and third timeslots are independently controlled allowing thereby detecting various portions said reflected pulses.

8. The time-of-flight detector of claim 7 wherein each of said groups further includes a fourth photodiode and wherein said shutter is further configured to facilitate detection of light by said fourth photodiode during a fourth timeslot.

9. The time-of-flight detector of claim 8 further comprising a controller configured for controlling operation of said light source and said shutter, and for controlling timing of said light pulses and timing of said each of the first, second and third timeslots.

10. The time-of-flight detector of claim 9 wherein said controller is configured to end said first timeslot before said reflected pulse is expected to reach back the detector, such that light detected during said first timeslot is ambient light, said controller is further configured to start said second timeslot after said pulse of light is emitted such that light detected during said second timeslot is a first portion of said reflected pulse, and said controller is further configured to start said third timeslot at the end of said second timeslot such that light detected during said third timeslot is a second portion of said reflected pulse.

11. The time-of-flight detector of claim 10 wherein said controller is further configured to determine the timing of said fourth time slot such that said fourth timeslot overlaps with a portion of said second timeslot and a portion of said third timeslot.

12. The time-of-flight detector of claim 8 wherein controller is configured for receiving data related to amount of light detected by each one of said first, second, third and fourth photodiodes, said controller is further configured for determining length and timing of each of said light pulses and the first, second, third and fourth timeslots in accordance with said data.

13. A method for time-of-flight detection by a detector having a plurality of photodiodes, the method comprising:
sending light pulses towards an object, such that said pulses are reflected back towards the detector;
arranging the photodiodes in groups, each group including at least a first photodiode, a second photodiode and a third photodiode;
detecting light by said first photodiode during a first timeslot, detecting light by said second photodiode during a second timeslot, and detecting light by said third photodiode during a third timeslot; and
controlling the timing of each of said first, second and third timeslots independently allowing thereby detecting various portions said reflected pulses.

14. The method according to claim 13 wherein each of said groups further includes a fourth photodiode and wherein said step of detecting light further includes detecting light by said fourth photodiode during a fourth timeslot.

15. The method according to claim 13 further comprising controlling the timing of said light pulses and timing of said each of the first, second and third timeslots.

16. The method according to claim 15 wherein said step of controlling includes ending said first timeslot before said reflected pulse is expected to reach back the detector, such that light detected during said first timeslot is ambient light, said step of controlling further includes starting said second timeslot after said pulse of light is emitted such that light detected during said second timeslot is a first portion of said reflected pulse, and said step of controlling further includes starting said third timeslot at the end of said second timeslot such that light detected during said third timeslot is a second portion of said reflected pulse.

17. The method according to claim 16 wherein said step of controlling further includes determining the timing of said fourth time slot such that said fourth timeslot overlaps with a portion of said second timeslot and a portion of said third timeslot.

18. The method according to claim 13 further comprising receiving data related to amount of light detected by each one of said first, second, third and fourth photodiodes, and determining length and timing of each of said light pulses and the first, second, third and fourth timeslots in accordance with said data.
